(19) United States
(12) Patent Application Publication
(10) Pub. No.: US 2015/0309557 A1
(43) Pub. Date: Oct. 29, 2015

(54) INSERTABLE HOUSING FOR ELECTRONIC DEVICE

(71) Applicants: Guowen Hu, Shanghai (CN); Wei Wen, Beaverton, OR (US)

(72) Inventors: Guowen Hu, Shanghai (CN); Wei Wen, Beaverton, OR (US)

(21) Appl. No.: 13/976,182

(22) PCT Filed: Jul. 2, 2012
(86) PCT No.: PCT/CN12/00918

§ 371 Date: May 23, 2014

(51) Int. Cl. G06F 1/32; G06F 1/18; A45C 11/00; G06F 1/16; H05K 5/02; H05K 5/00

(52) U.S. Cl. CPC G06F 1/3262; H05K 5/0247; H05K 5/0004; H05K 5/0086; A45C 11/00; G06F 1/1632; G06F 1/1637; G06F 1/189; G06F 1/3218; G06F 1/3287; A45C 2011/003

(57) ABSTRACT

In one embodiment an electronic device comprises a body dimensioned to fit within a cavity of a housing, a display, an electrical interface comprising electrical contacts to establish an electrical connection with electrical contacts disposed in the cavity of the housing, logic configured to detect an activation signal for the display when the electronic device is disposed in the cavity in a first orientation and in response to the activation signal, activate at least a portion of the display that is visible through a viewing region when the electronic device is disposed in the cavity in the first orientation. Other embodiments may be described.

### BACKGROUND

The subject matter described herein relates generally to the field of electronic devices and more particularly to an insertable housing for one or more electronic devices.

Many electronic devices such as tablet computers, electronic readers, and the like utilize a touch sensitive display as an input/output interface and therefore lack fully independent input/output interfaces such as a keyboard, mouse, touchpad, or the like. Many such electronic devices utilize network interface cards or other network access technology which permits the devices to remain connected to an electronic communication network even when in a low-power operating state. This feature is sometimes referred to as “always on, always connected” or by the acronym AOAC, and enables an electronic device to receive network-based information updates such as electronic mail, status updates, and the like even when the device is in a low-power operating mode. Further, many such electronic devices face limitations due to battery power issues.

Accordingly, housings to address one or more of these issues may find utility.

### BRIEF DESCRIPTION OF THE DRAWINGS

The detailed description is described with reference to the accompanying figures.

FIGS. 1A-1B and FIG. 2 are schematic illustrations of an exemplary system comprising a housing and an electronic device, in accordance with some embodiments.

FIG. 3 is a schematic illustration of an exemplary electronic device in accordance with some embodiments.

FIG. 4 is a flowchart illustrating operations of a controller in a operate an electronic device in accordance with some embodiments.

FIG. 5 is a schematic illustration of an exemplary electronic device which may be modified to include a locking hinge assembly in accordance with some embodiments.

### DETAILED DESCRIPTION

Described herein are exemplary embodiments of housings for an electronic device and electronic devices which are adapted to work with such housings. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

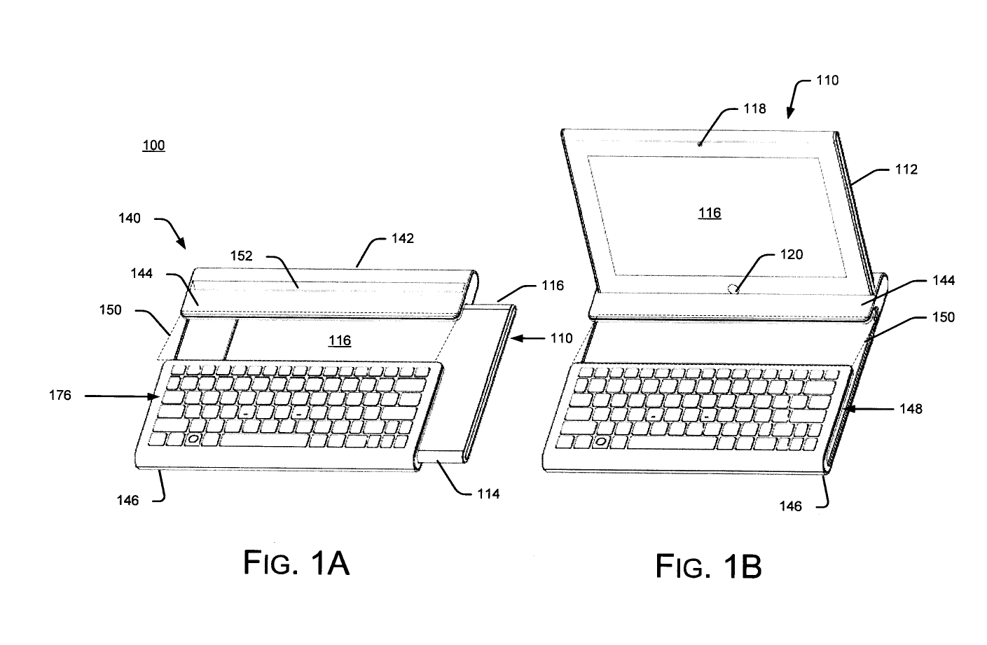

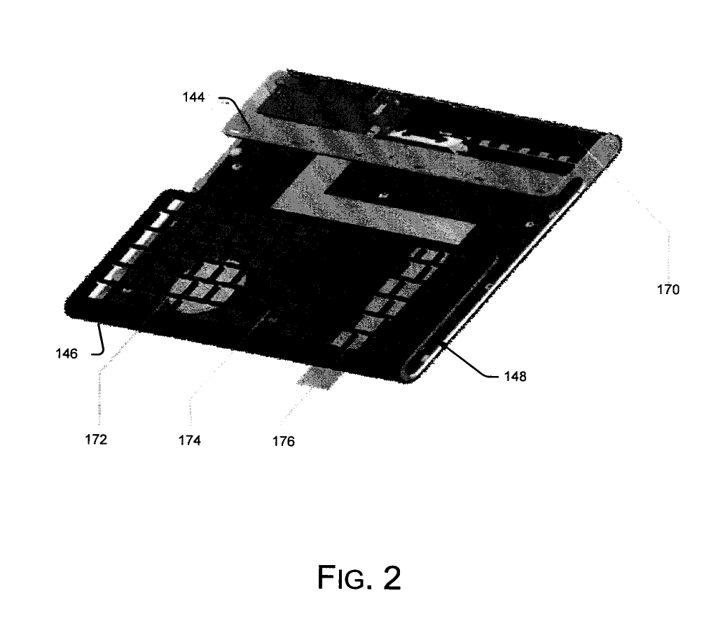

FIGS. 1A-1B and FIG. 2 are schematic illustrations of an exemplary system 100 for an electronic device in accordance with some embodiments. In one embodiment, system 100 includes an electronic device 110 which includes a body 112 comprising a first edge 114 and a second edge 116. A display 116 is positioned on a first major surface of the electronic device 112. In some embodiments electronic device 110 may be embodied as a tablet computer, an electronic reader, or the like and may include one or more accompanying input/output devices including a touch screen on display 116, a camera 118, or a microphone 120.

System 100 further comprises a housing 140 comprising a body 142 having a first major surface 144 and a second major surface 146 opposite the first major surface 144. The first major surface 144 and the second major surface 146 define a cavity 148 to receive the electronic device 110 in a first orientation, as depicted in FIG. 1A. In addition, the first major surface 144 defines a viewing region 150 to view a portion of the electronic device 110 when the electronic device 110 is disposed in the cavity 148. The first major surface 144 further defines a channel 152 to receive the first edge 114 of electronic device 110 to hold the electronic device 110 in a second orientation, different than the first orientation, as depicted in FIG. 1B.

Referring to FIG. 1A, when the electronic device 110 slides into the cavity 148 from a side of the body 142 at least a portion of the display 116 is visible through the viewing region 150 when the electronic device is disposed in the cavity in the first orientation. Further, in some embodiments the housing comprises electrical contacts disposed in the cavity 140 to establish an electrical connection with mating electrical contacts on the electronic device 110.

Referring to FIG. 1B, when the electronic device 110 slides into the channel 152 and the entire display 116 is visible when the electronic device 110 is disposed in the channel 152 in the second orientation. In some embodiments the housing comprises electrical contacts disposed in the channel 152 to establish an electrical connection with electrical contacts on the electronic device 110.

Referring to FIG. 2, the housing 140 may comprise one or more power sources 170 such as one or more batteries, charging module 172, a near field communication module 174, and one or more input/output devices 176 such as a keyboard, track pad, or the like.

In some embodiments the one or more power sources 170 and input/output devices 176 may be communicatively coupled to the electronic device 110 via an electrical connection when the electronic device 110 is disposed in the cavity 148 in the first orientation. Similarly, the one or more power sources 170 and input/output devices may be electrically coupled to the electronic device 110 via an electrical connection when the electronic device 110 is disposed in the channel 152 in the second orientation.

In some embodiments the charging module 172 may be a wireless charging module capable of charging the power source in electronic device without an electrical connection between the housing 140 and the device. Similarly, input/output device(s) 176 may be wireless devices. Thus, in some embodiments an electrical connection between the housing 140 and the electronic device 110 is not required.

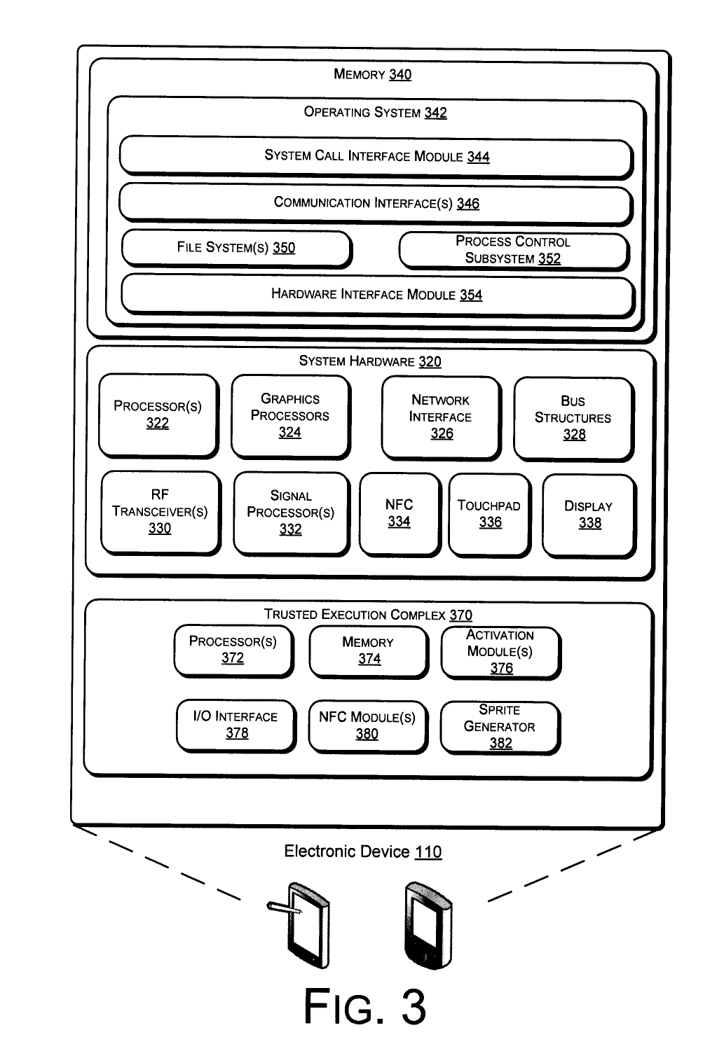

FIG. 3 is a schematic illustration of an exemplary electronic device 110. As illustrated in FIG. 3, electronic device 110 may be embodied as a conventional mobile device such as a mobile phone, tablet computer, electronic reader, personal digital assistant (PDA), or the like.

In some embodiments an electronic device may include a trusted execution complex, which may also be referred to as a trusted execution engine or sometimes as a secure element or a manageability engine. The trusted execution complex may comprise one or more controllers that are separate from the primary execution complex, sometimes referred to as an untrusted execution complex. The separation may be physical in the sense that the trusted execution complex may be physically separate from the untrusted execution complex. Alternatively, the trusted execution complex may logical in the sense that the trusted execution complex may be hosted on same chip or chipset that hosts the untrusted execution complex, but separated at the silicon level such that the trusted execution complex is secure.

In various embodiments, electronic device 110 may include or be coupled to one or more accompanying input/output devices including a display, one or more speakers, a keyboard, one or more other I/O device(s), a mouse, or the like. Exemplary 110 device(s) may include a touch screen, a voice-activated input device, a track ball, a geolocation device, an accelerometer/gyroscope, biometric feature input devices, and any other device that allows the electronic device 110 to receive input from a user.

The electronic device 110 includes system hardware 320 and memory 340, which may be implemented as random access memory and/or read-only memory. A file store may be communicatively coupled to electronic device 110. The file store may be internal to computing device 110 such as, e.g., eMMC, SSD, one or more hard drives, or other types of storage devices. File store may also be external to computer 110 such as, e.g., one or more external hard drives, network attached storage, or a separate storage network.

System hardware 320 may include one or more processors 322, graphics processors 324, network interfaces 326, and bus structures 328. In one embodiment, processor 322 may be embodied as an Intel® Atom™ processors, Intel® Atom™ based System-on-a-Chip (SOC) or

Intel ® Core2 Duo® processor available from Intel Corporation, Santa Clara, Calif., USA. As used herein, the term “processor” means any type of computational element, such as but not limited to, a microprocessor, a microcontroller, a complex instruction set computing (CISC) microprocessor, a reduced instruction set (RISC) microprocessor, a very long instruction word (VLIW) microprocessor, or any other type of processor or processing circuit.

Graphics processor(s) 324 may function as adjunct processor that manages graphics and/or video operations. Graphics processor(s) 324 may be integrated onto the motherboard of electronic device 110 or may be coupled via an expansion slot on the motherboard.

In one embodiment, network interface 326 could be a wired interface such as an Ethernet interface (see, e.g., Institute of Electrical and Electronics Engineers/IEEE 802.3-2002) or a wireless interface such as an IEEE 802.11a, b or g-compliant interface (see, e.g., IEEE Standard for IT-Telecommunications and information exchange between systems LAN/MAN-Part II: Wireless LAN Medium Access Control (MAC) and Physical Layer (PHY) specifications Amendment 4: Further Higher Data Rate Extension in the 2.4 GHz Band, 802.11G-2003). Another example of a wireless interface would be a general packet radio service (GPRS) interface (see, e.g., Guidelines on GPRS Handset Requirements, Global System for Mobile Communications/GSM Association, Ver. 3.0.1, December 2002).

Bus structures 328 connect various components of system hardware 128. In one embodiment, bus structures 128 may be one or more of several types of bus structure(s) including a memory bus, a peripheral bus or external bus, and/or a local bus using any variety of available bus architectures including, but not limited to, 11-bit bus, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Universal Serial Bus (USB), Advanced Graphics Port (AGP), Personal Computer Memory Card International Association bus (PCMCIA), and Small Computer Systems Interface (SCSI), a High Speed Synchronous Serial Interface (HSI), a Serial Low-power Inter-chip Media Bus (SLIMbus®), or the like.

Electronic device 110 may include an RF transceiver 330 to transceive RF signals, a Near Field Communication (NFC) radio 334, and a signal processing module 332 to process signals received by RF transceiver 330. RF transceiver may implement a local wireless connection via a protocol such as, e.g., Bluetooth or 802.11X. IEEE 802.11a, b or g-compliant interface (see, e.g., IEEE Standard for IT-Telecommunications and information exchange between systems LAN/MAN-Part II; Wireless LAN Medium Access Control (MAC) and Physical Layer (PHY) specifications Amendment 4: Further Higher Data Rate Extension in the 2.4 GHz Band, 802.11G-2003). Another example of a wireless interface would be a WCDMA, LTE, general packet radio service (GPRS) interface (see, e.g., Guidelines on GPRS Handset Requirements, Global System for Mobile Communications/GSM Association, Ver. 3.0.1, December 2002).

Electronic device 110 may further include one or more input/output interfaces such as, e.g., a keypad 336 and a display 338. In some embodiments electronic device 110 may not include a keypad and use the touch panel for input.

Memory 340 may include an operating system 342 for managing operations of computing device 110. In one embodiment, operating system 342 includes a hardware interface module 354 that provides an interface to system hardware 320. In addition, operating system 340 may include a file system 350 that manages files used in the operation of computing device 110 and a process control subsystem 352 that manages processes executing on computing device 110.

Operating system 342 may include (or manage) one or more communication interfaces 346 that may operate in conjunction with system hardware 320 to transceive data packets and/or data streams from a remote source. Operating system 342 may further include a system call interface module 344 that provides an interface between the operating system 342 and one or more application modules resident in memory 330. Operating system 342 may be embodied as a UNIX operating system or any derivative thereof (e.g., Linux, Android, etc.) or as a Regions® brand operating system, or other operating systems.

Electronic device 110 may comprise a trusted execution engine 370. In some embodiments the trusted execution engine 370 may be implemented as an independent integrated circuit located on the motherboard of the electronic device 110, while in other embodiments the trusted execution engine 370 may implemented as a dedicated processor block on the same SOC die, while in other embodiments the trusted execution engine may be implemented on a portion of the processor(s) 322 that is segregated from the rest of the processor(s) using hardware enforced mechanisms

In the embodiment depicted in FIG. 1 the trusted execution engine 370 comprises a processor 372, a memory module 374, one or more activation module 376, an 110 module 378, a near field communication (NFC) module 380, and a sprite generator 386. In some embodiments the memory module 374 may comprise a persistent flash memory module and the various functional modules may be implemented as logic instructions encoded in the persistent memory module, e.g., firmware or software. The 110 module 378 may comprise a serial I/O module or a parallel I/O module. Because the trusted execution engine 370 is separate from the main processor(s) 322 and operating system 342, the trusted execution engine 370 may be made secure, i.e., inaccessible to hackers who typically mount SW attacks from the host processor 322.

In some embodiments the trusted execution complex 370 in electronic device 110 may be implemented on a low power consumption chip. In some embodiments the activation module 376 implements logic to detect when the electronic device in different modes depending upon whether the electronic device 110 is in cavity 148 of the housing 140, in the channel 152 of the housing 140, or operating independently from the housing 140. In some embodiments the operations depicted in FIG. 6 may be implemented by the activation module 176, alone or in combination with other components executing on the trusted execution complex 370 of the electronic device 110.

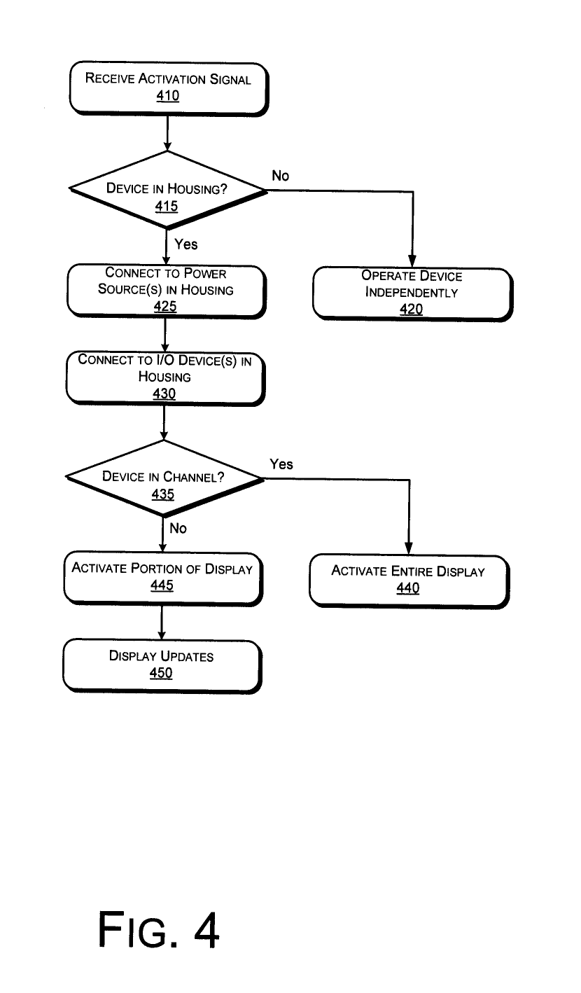

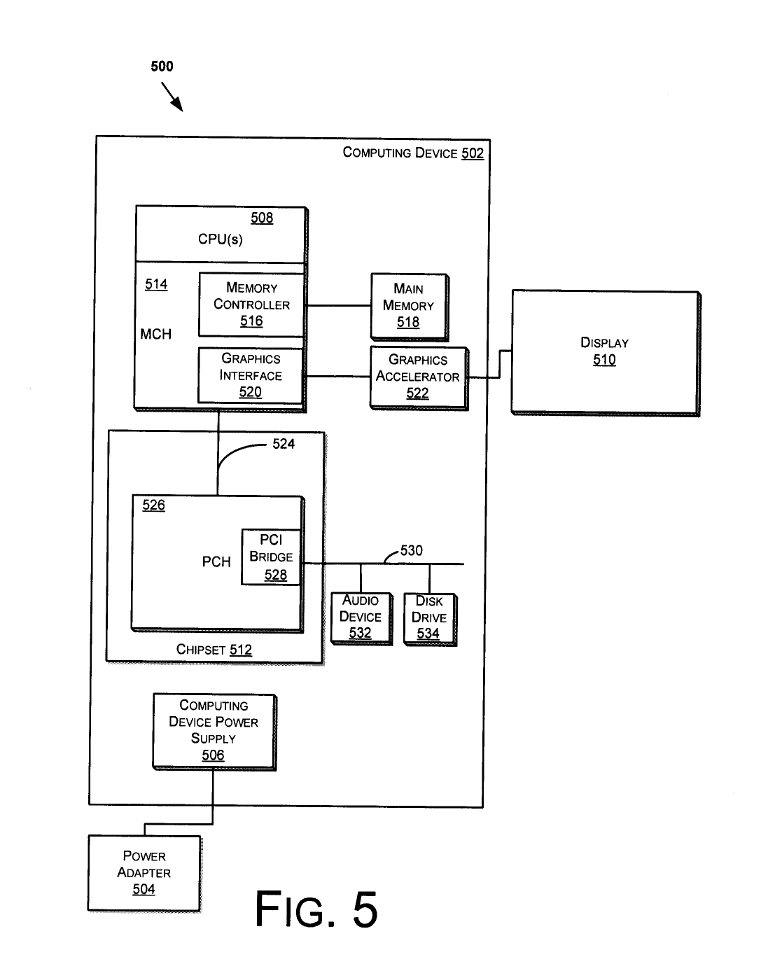

Referring to FIG. 4, at operation 410 the controller receives an activation signal. In some embodiments the action signal may be generated when the a user touches the display 116 of the electronic device 110, or when a user activates a power switch on electronic device 110.

In response to the signal, at operation 415, the activation module 376 determines whether the electronic device 110 is in the housing. By way of example, in embodiments in which the electronic device 110 is coupled to the housing 140 by an electrical connection the activation module 376 may detect whether the electronic device 110 has established an electrical connection with electrical contacts in the cavity 148 or in the channel 152. If, at operation 415, the electronic device 110 is not in the housing then control passes to operation 420 and the device is operated independently.

By contrast, if at operation 415 the electronic device 110 is in the housing then control passes to operation 425 and the electronic device 110 is coupled to one or more power sources in the housing 140. At operation 430 the electronic device is coupled to one or more input/output devices 160 in the housing.

At operation 435 it is determined whether the electronic device 110 is coupled to the channel 152. If, at operation 435 the device is coupled to the channel, then control passes to operation 440 and the entire display is activated so that a user may interact with the electronic device in the configuration presented in FIG. 1B.

By contrast, if at operation 435 the electronic device is not coupled to the channel 152, then the device is disposed in the cavity 148, and at operation 445 only the portion of the display 116 visible through the region 150 is activated. By way of example, in some embodiments the activation module 376 may invoke the services of a secure sprite generator 382 to generate a dialog box on a portion of the display 116. The dialog box may require a user to log in, e.g. by entering a password.

Assuming a successful login, at operation 620 the controller presents at least one network-based information update on the dialog box. By way of example, in some embodiments a user may wish to receive notifications of electronic mail received, status updates, stock prices, weather information, or the like. These information updates may be presented on the dialog box for viewing by a user.

As described above, in some embodiments the electronic device may be embodied as a computer-based system. FIG. 7 is a schematic illustration of a computer-based system 500 in accordance with some embodiments. The computer system 500 includes a computing device 502 and a power adapter 504 (e.g., to supply electrical power to the computing device 502). The computing device 502 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 502 (e.g., through a computing device power supply 506) from one or more of the following sources: one or more battery packs, an alternating current (AC) outlet (e.g., through a transformer and/or adaptor such as a power adapter 504), automotive power supplies, airplane power supplies, and the like. In some embodiments, the power adapter 504 may transform the power supply source output (e.g., the AC outlet voltage of about 110 VAC to 240 VAC) to a direct current (DC) voltage ranging between about 5 VDC to 12.6 VDC. Accordingly, the power adapter 504 may be an AC/DC adapter.

The computing device 502 may also include one or more central processing unit(s) (CPUs) 508. In some embodiments, the CPU 508 may be one or more processors in the Pentium® family of processors including the Pentium® II processor family, Pentium® III processors, Pentium® IV, or CORE2 Duo processors available from Intel® Corporation of Santa Clara, Calif. Alternatively, other CPUs may be used, such as Intel's Itanium®, XEON□, and Celeron® processors. Also, one or more processors from other manufactures may be utilized. Moreover, the processors may have a single or multi core design.

A chipset 512 may be coupled to, or integrated with, CPU 508. The chipset 512 may include a memory control hub (MCH) 514. The MCH 514 may include a memory controller 516 that is coupled to a main system memory 518. The main system memory 518 stores data and sequences of instructions that are executed by the CPU 508, or any other device included in the system 500. In some embodiments, the main system memory 518 includes random access memory (RAM); however, the main system memory 518 may be implemented using other memory types such as dynamic RAM (DRAM), synchronous DRAM (SDRAM), and the like. Additional devices may also be coupled to the bus 510, such as multiple CPUs and/or multiple system memories.

The MCH 514 may also include a graphics interface 520 coupled to a graphics accelerator 522. In some embodiments, the graphics interface 520 is coupled to the graphics accelerator 522 via an accelerated graphics port (AGP). In some embodiments, a display (such as a flat panel display) 540 may be coupled to the graphics interface 520 through, for example, a signal converter that translates a digital representation of an image stored in a storage device such as video memory or system memory into display signals that are interpreted and displayed by the display. The display 540 signals produced by the display device may pass through various control devices before being interpreted by and subsequently displayed on the display.

A hub interface 524 couples the MCH 514 to an platform control hub (PCH) 526. The PCH 526 provides an interface to input/output (I/O) devices coupled to the computer system 500. The PCH 526 may be coupled to a peripheral component interconnect (PCI) bus. Hence, the PCH 526 includes a PCI bridge 528 that provides an interface to a PCI bus 530. The PCI bridge 528 provides a data path between the CPU 508 and peripheral devices. Additionally, other types of I/O interconnect topologies may be utilized such as the PCI Express® architecture, available through Intel® Corporation of Santa Clara, Calif.

The PCI bus 530 may be coupled to an audio device 532 and one or more disk drive(s) 534. Other devices may be coupled to the PCI bus 530. In addition, the CPU 508 and the MCH 514 may be combined to form a single chip. Furthermore, the graphics accelerator 522 may be included within the MCH 514 in other embodiments.

Additionally, other peripherals coupled to the PCH 526 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 502 may include volatile and/or nonvolatile memory.

FIGS. 8A and 8B are schematic, perspective views of an electronic device in accordance with some embodiments. In the embodiment depicted in FIGS. 8A and 8B the second section 162 of the electronic device 108 translates laterally along an axis that is perpendicular to the axis of the hinge assembly about which the second section 162 rotates. In this embodiment the second section 162 may be configured with a latch mechanism which enables part of the second section 162 to translate laterally on tracks 164 to expose a portion of the display 104.

The terms “logic instructions” as referred to herein relates to expressions which may be understood by one or more machines for performing one or more logical operations. For example, logic instructions may comprise instructions which are interpretable by a processor compiler for executing one or more operations on one or more data objects. However, this is merely an example of machine-readable instructions and embodiments are not limited in this respect.

The terms “computer readable medium” as referred to herein relates to media capable of maintaining expressions which are perceivable by one or more machines. For example, a computer readable medium may comprise one or more storage devices for storing computer readable instructions or data. Such storage devices may comprise storage media such as, for example, optical, magnetic or semiconductor storage media. However, this is merely an example of a computer readable medium and embodiments are not limited in this respect.

The term “logic” as referred to herein relates to structure for performing one or more logical operations. For example, logic may comprise circuitry which provides one or more output signals based upon one or more input signals. Such circuitry may comprise a finite state machine which receives a digital input and provides a digital output, or circuitry which provides one or more analog output signals in response to one or more analog input signals. Such circuitry may be provided in an application specific integrated circuit (ASIC) or field programmable gate array (FPGA). Also, logic may comprise machine-readable instructions stored in a memory in combination with processing circuitry to execute such machine-readable instructions. However, these are merely examples of structures which may provide logic and embodiments are not limited in this respect.

Some of the methods described herein may be embodied as logic instructions on a computer-readable medium. When executed on a processor, the logic instructions cause a processor to be programmed as a special-purpose machine that implements the described methods. The processor, when configured by the logic instructions to execute the methods described herein, constitutes structure for performing the described methods. Alternatively, the methods described herein may be reduced to logic on, e.g., a field programmable gate array (FPGA), an application specific integrated circuit (ASIC) or the like.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” or “some embodiments” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1-21. (canceled)

22. A housing for an electronic device, comprising:
a body having a first major side and a second major surface and defining a cavity to receive the electronic device in a first orientation, wherein the first major surface defines:
a viewing region to allow a view of a portion of the electronic device when the electronic device is disposed in the cavity; and
a channel to receive the electronic device in a second orientation, different than the first orientation.

23. The housing of claim 22, wherein the electronic device is to slide into the cavity from a side of the body and comprises a display, at least a portion of which is visible through the viewing region when the electronic device is disposed in the cavity in the first orientation.

24. The housing of claim 23, wherein the housing comprises electrical contacts disposed in the cavity to establish an electrical connection with electrical contacts of the electronic device.

25. The housing of claim 24, wherein the housing comprises at least one of:
an input/output device communicatively coupled to the electronic device via the electrical connection when the electronic device is disposed in the cavity in the first orientation;
a power source electrically coupled to the electronic device via the electrical connection when the electronic device is disposed in the cavity in the first orientation.

26. The housing of claim 22, wherein the electronic device is positionable in channel and comprises a display, at least a portion of which is visible when the electronic device is disposed in the channel in the second orientation.

27. The housing of claim 26, wherein the housing comprises electrical contacts disposed in the channel to establish an electrical connection with electrical contacts of the electronic device.

28. The housing of claim 27, wherein the housing comprises at least one of:
an input/output device communicatively coupled to the electronic device via the electrical connection when the electronic device is disposed in the channel in the second orientation;
a power source electrically coupled to the electronic device via the electrical connection when the electronic device is disposed in the channel in the second orientation.

29. A system, comprising:
an electronic device; and
a housing for the electronic device, comprising:
a body having a first major surface and a second major surface and defining a cavity to receive the electronic device in a first orientation, wherein the first major surface defines:
a viewing region to allow a view of a portion of the electronic device when the electronic device is disposed in the cavity; and
a channel to receive the electronic device in a second orientation, different than the first orientation.

30. The system of claim 29, wherein the electronic device is to slide into the cavity from a side of the body and comprises a display, at least a portion of which is visible through the viewing region when the electronic device is disposed in the cavity in the first orientation.

31. The system of claim 30, wherein the housing comprises electrical contacts disposed in the cavity to establish an electrical connection with electrical contacts of the electronic device.

32. The system of claim 31, wherein the housing comprises at least one of:
an input/output device communicatively coupled to the electronic device via the electrical connection when the electronic device is disposed in the cavity in the first orientation;
a power source electrically coupled to the electronic device via the electrical connection when the electronic device is disposed in the cavity in the first orientation.

33. The system of claim 31, wherein the electronic device comprises logic to:
detect an activation signal for the display when the electronic device is disposed in the cavity in the first orientation; and
in response to the activation signal, activate at least a portion of the display that is visible through the viewing region when the electronic device is disposed in the cavity in the first orientation.

34. The system of claim 29, wherein the electronic device slides into the channel and comprises a display, at least a portion of which is visible when the electronic device is disposed in the channel in the second orientation.

35. The system of claim 34, wherein the housing comprises electrical contacts disposed in the channel to establish an electrical connection with electrical contacts of the electronic device.

36. The system of claim 35, wherein the housing comprises at least one of:
an input/output device communicatively coupled to the electronic device via the electrical connection when the electronic device is disposed in the channel in the second orientation;
a power source electrically coupled to the electronic device via the electrical connection when the electronic device is disposed in the channel in the second orientation.

37. The system of claim 35, wherein the electrical device comprises logic to:
detect an activation signal for the display when the electronic device is disposed in the channel in the second orientation; and
in response to the activation signal, activate the display.

38. An electronic device, comprising:
a body dimensioned to fit within a cavity of a housing;
a display;
an electrical interface comprising electrical contacts to establish an electrical connection with electrical contacts disposed in the cavity of the housing;
logic configured to:
detect an activation signal for the display when the electronic device is disposed in the cavity in a first orientation; and
in response to the activation signal, activate at least a portion of the display that is visible through a viewing region when the electronic device is disposed in the cavity in the first orientation.

39. The electronic device of claim 38, wherein the logic is further configured to:
generate a dialog box on a portion of a display; and
present, in the dialog box, at least one network-based information update.

40. The electronic device of claim 38, wherein the body is further dimensioned to be positioned in a channel in a second orientation, different than the first orientation.

41. The electronic device of claim 38, wherein the logic is further configured to:
detect a connection signal which indicates that the electronic device is positioned in the channel in the second orientation; and
in response to the activation signal, activate the display.
